(19) United States
(12) Patent Application Publication
(10) Pub. No.: US 2009/0075485 A1
(43) Pub. Date: Mar. 19, 2009

(54) METHOD FOR FORMING PATTERN OF SEMICONDUCTOR DEVICE

(75) Inventors: Keun Do BAN, Yongin-si (KR); Jun Hyeub SUN, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc, Icheon-si (KR)

(21) Appl. No.: 12/163,864

(22) Filed: Jun. 27, 2008

(30) Foreign Application Priority Data
Sep. 18, 2007 (KR) 10-2007-0094837

(51) Int. Cl. H01L 21/308

(52) U.S. Cl. 438/751; 257/E21.038; 257/E21.039; 257/E21.235; 257/E21.236; 257/E21.219

(57) ABSTRACT

A method for forming a fine pattern of a semiconductor device comprises: forming a first hard mask film and an etch barrier film over a semiconductor substrate; forming a sacrificial pattern over the etch barrier film; forming a spacer on sidewalls of the sacrificial pattern; removing the sacrificial pattern; etching the etch barrier film and the hard mask film with the spacer as an etch mask to form an etch barrier pattern and a hard mask pattern; and removing the spacer and the etch barrier pattern, thereby improving yield and reliability of the device.

### CROSS-REFERENCE TO RELATED APPLICATION

Priority to Korean patent application number 10-2007-0094837, filed on Sep. 18, 2007, which is incorporated by reference in its entirety, is claimed.

### BACKGROUND OF THE INVENTION

The present invention relates to a method for forming a pattern of a semiconductor device that comprises forming a line/space pattern over a semiconductor substrate that defines a fine pattern which improves yield and reliability of the device.

As semiconductor devices become smaller and highly integrated, a chip area is increased in proportion to an increase in memory capacity. However, a cell area of the semiconductor device, which contains patterns, is reduced.

In order to secure a desired memory capacity, more patterns are formed in a limited cell area, so that a critical dimension of the pattern is reduced. As a result, a lithography process is required to advance to form more finer patterns.

In the lithography process, a photoresist is formed onto a substrate. An exposure process is performed on the photoresist with an exposure mask where a fine pattern is defined using a light source having a wavelength of 356 nm, 248 nm, 193 nm or 153 nm. A development process is then performed to form a photoresist pattern that defines a fine pattern.

The resolution of the lithography process is determined by a wavelength (λ) and a numerical aperture (NA) as shown in the equation R=k1×λ/NA. The k1 represents a process constant which has a physical limit, which makes it impossible to reduce its value by a general method. Instead, a new photoresist material is required which has a high reactivity to the short wavelength with an exposer. As a result, it is difficult to form a fine pattern having a CD of less than the short wavelength. One solution is a double patterning technology, which uses overlapping patterns to increase the resolution of existing exposer equipment.

FIGS. 1a to 1d are cross-sectional diagrams illustrating a conventional method for forming a fine pattern of a semiconductor device. In FIG. 1a, an underlying layer 20 is formed over a semiconductor substrate 10, and a hard mask layer (not shown) is formed over the underlying layer 20.

A first photoresist film (not shown) is formed over the hard mask layer (not shown). The first photoresist film (not shown) is exposed and developed with a mask 50 that defines a pitch that is two times larger than a fine pattern to form a first photoresist pattern 40. The hard mask layer (not shown) is etched with the first photoresist pattern 40 as a mask to form a first hard mask pattern 30.

Referring to FIG. 1b, the first photoresist pattern 40 is removed, and a second photoresist film (not shown) is formed over the first hard mask pattern 30. The pattern of the mask 50 used in FIG. 1a is aligned with an offset with the first hard mask pattern 30. An exposure and development process is performed to form a second photoresist pattern 55. As the size of the semiconductor device becomes smaller, it becomes difficult to accurately align the second photoresist pattern 55 with the first hard mask pattern 30.

Referring to FIG. 1c, the first hard mask pattern 30 is etched with the second photoresist pattern 55 as a mask to form a second hard mask pattern 35 that defines a fine pattern. The second photoresist pattern 55 is then removed.

Referring to FIG. 1d, the underlying layer 20 is etched with the second hard mask pattern 35 as a mask to form a fine pattern 25. As shown in the figure the alignment process for the second photoresist pattern 55 is not performed accurately, so that a CD of the pattern is not uniform.

FIGS. 2a to 2d are cross-sectional diagrams illustrating a conventional method for forming a fine pattern of a semiconductor device using a dual trench approach technology. The dual line approach technology is used when it is difficult to form patterns which are close to each other although a CD of a fine pattern can be obtained with the resolution of an exposer.

In FIG. 2a, an underlying layer 65, a first hard mask layer 70, a second hard mask layer (not shown) and a first photoresist film (not shown) are formed over a semiconductor substrate 60. The first photoresist film (not shown) is exposed and developed with a mask 90 to form a first photoresist pattern 85a, which has a pitch that is twice as large as the desired fine pattern. The hard mask layer (not shown) is etched with the first photoresist pattern 85a as a mask to form a second hard mask pattern 80.

Referring to FIG. 2b, the first photoresist pattern 85a is removed. A second photoresist film (not shown) is formed over the semiconductor substrate 60 including the second hard mask pattern 80.

The pattern of the mask 90 used in FIG. 2a is aligned with an offset with the second hard mask pattern 80. An exposure and development process is performed on the second photoresist film (not shown) to form a second photoresist pattern 85b. The second photoresist pattern 85b is formed between the second hard mask patterns 80.

Referring to FIG. 2c, the first hard mask pattern 75 is etched with the second photoresist pattern 85b and the second hard mask pattern 80 as a mask to form a first hard mask pattern 75. The second photoresist pattern 85b is then removed. The underlying layer 65 is etched with the first hard mask pattern 75 and the second hard mask pattern 80 as a mask to form a fine pattern 67. When the alignment process for creating the second photoresist pattern 85b is not performed accurately, a CD of the pattern will not be uniform.

As mentioned above, in the conventional method, it is difficult to form a fine pattern due to a resolution limit of an exposer. When an exposure process is performed twice in the double patterning process to overcome the limit, patterns may be misaligned to degrade yield and reliability of the semiconductor device.

### BRIEF SUMMARY OF THE INVENTION

Various embodiments of the present invention relate to a method for forming a pattern of a semiconductor device that comprises forming a line/space pattern over a semiconductor substrate; forming a spacer on the sidewalls of the line pattern; using the spacer as a hard mask pattern that defines a fine pattern and thereby improving yield and reliability of the device.

According to an embodiment of the present invention, a method for forming a semiconductor device comprises: forming a hard mask film and an etch barrier film over a semiconductor substrate; forming a sacrificial pattern over the etch barrier film; forming a spacer on sidewalls of the sacrificial pattern; removing the sacrificial pattern; etching the etch barrier film and the hard mask film with the spacer as an etch mask to form a etch barrier pattern and a hard mask pattern; and removing the spacer and the etch barrier pattern.

According to an embodiment of the present invention, a method for forming a semiconductor device comprises: forming a hard mask film and an etch barrier film over a semiconductor substrate; forming a sacrificial oxide pattern over the etch barrier film; forming a spacer on sidewalls of the sacrificial oxide pattern; removing the sacrificial oxide pattern; forming a first photoresist pattern exposing a partial portion of the spacer over the etch barrier film; etching an exposed portion of the spacer with the first photoresist pattern as an etch mask; removing the first photoresist pattern to divide the spacer into spacer patterns; forming a second photoresist pattern determining a dummy pattern on the etch barrier film in a peri area; etching the etch barrier film and the hard mask film with the second photoresist pattern and the spacer patterns as an etch mask to form a etch barrier pattern and a hard mask pattern; and removing the second photoresist pattern and the spacer patterns.

According to an embodiment of the present invention, a method for forming a semiconductor device comprises: forming a first hard mask film over a semiconductor substrate; forming an etch barrier film and a polysilicon film over the first hard mask film; forming a second hard mask pattern over the polysilicon film; forming a spacer on sidewalls of the second hard mask pattern; removing the second hard mask pattern; forming a first photoresist pattern determining a dummy pattern on the polysilicon film in a peri area; etching the polysilicon film with the first photoresist pattern and spacer as an etch mask to form a polysilicon pattern and a dummy polysilicon pattern; removing the first photoresist pattern and the spacer; forming a second photoresist pattern exposing a partial portion of the polysilicon pattern over the polysilicon film; etching an exposed portion of the polysilicon pattern with the second photoresist pattern as an etch mask to divide the polysilicon pattern into polysilicon line patterns; removing the second photoresist pattern; etching the etch barrier film and the first hard mask film with the polysilicon line patterns and the dummy polysilicon pattern as an etch mask; and removing the polysilicon line patterns, the dummy polysilicon pattern and the etch barrier film.

### BRIEF DESCRIPTION OF THE DRAWINGS

FIGS. 1a to 1d are cross-sectional diagrams illustrating a conventional method for forming a fine pattern of a semiconductor device.

FIGS. 2a to 2d are cross-sectional diagrams illustrating a conventional method for forming a fine pattern of a semiconductor device.

FIGS. 3a to 3d are cross-sectional diagrams illustrating a method for forming a fine pattern of a semiconductor device according to an embodiment of the present invention.

FIGS. 4a to 4g are cross-sectional diagrams illustrating a method for forming a fine pattern of a semiconductor device according to an embodiment of the present invention.

FIGS. 5a to 5d are cross-sectional diagrams illustrating a method for forming a fine pattern of a semiconductor device according to an embodiment of the present invention.

FIGS. 6a to 6h are cross-sectional diagrams illustrating a method for forming a fine pattern of a semiconductor device according to an embodiment of the present invention.

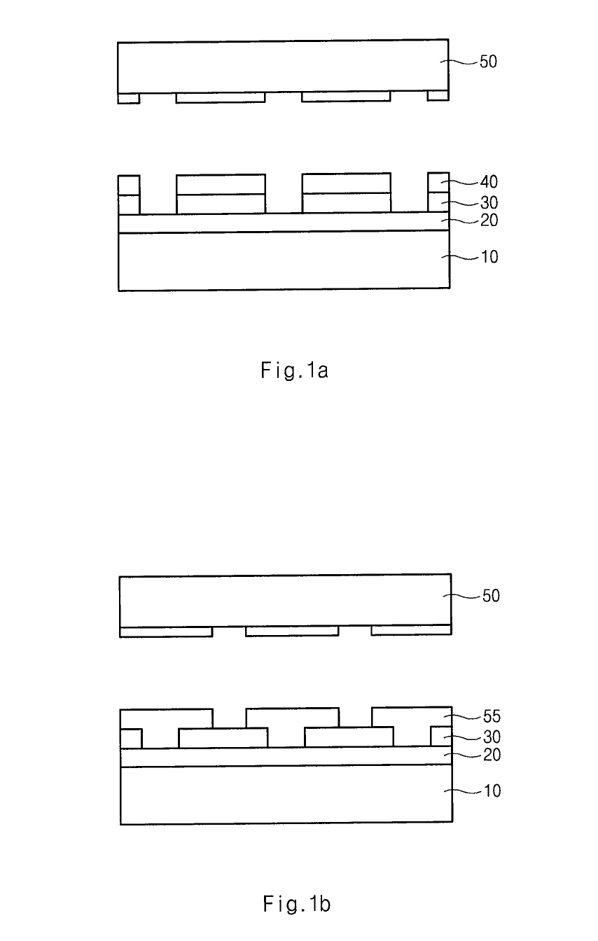

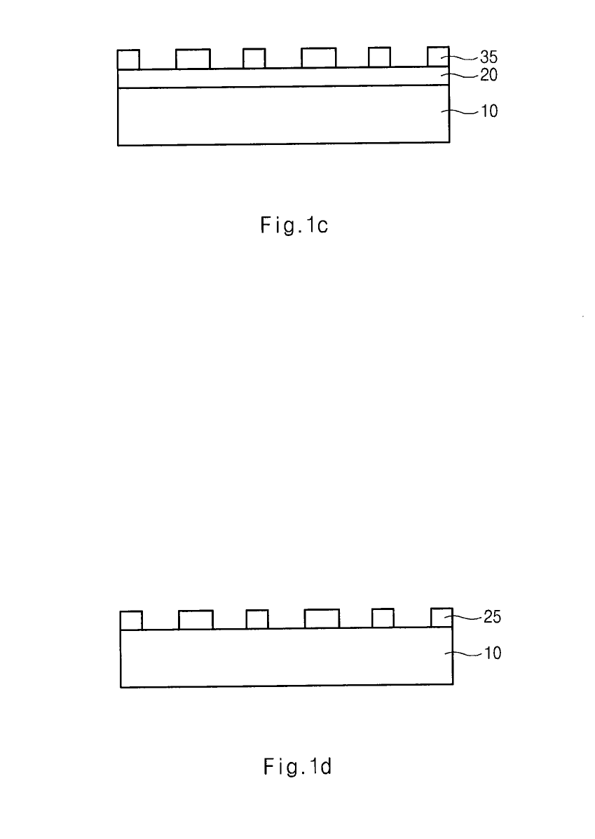

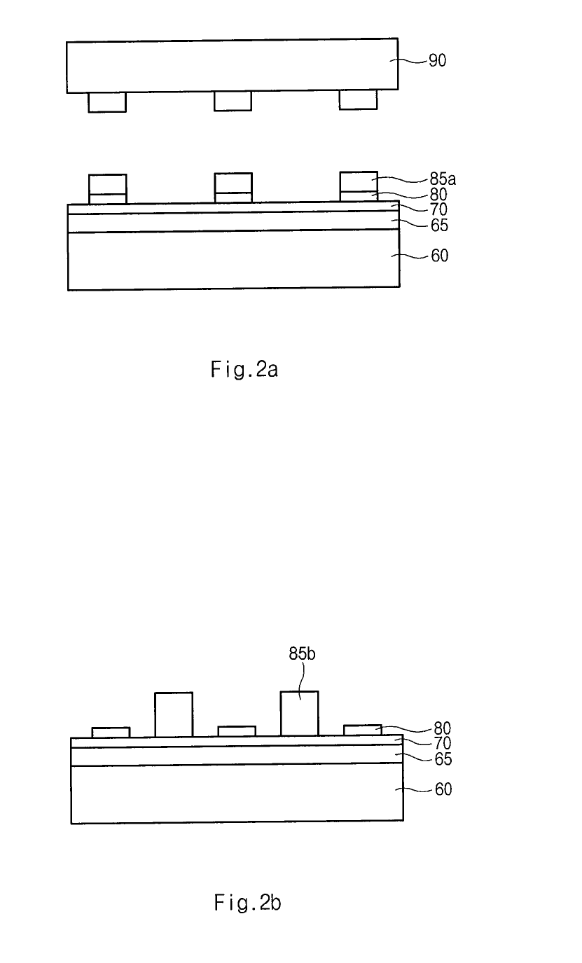

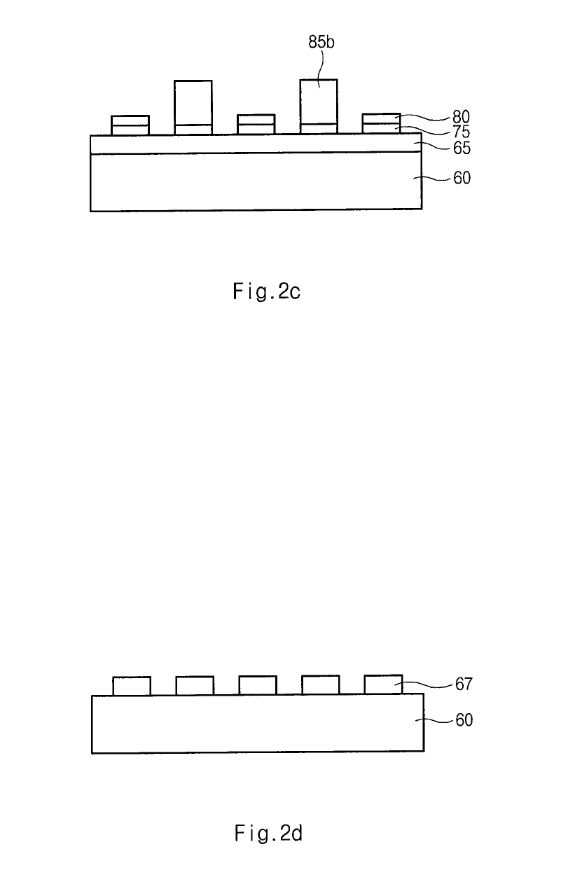

### DESCRIPTION OF EMBODIMENTS

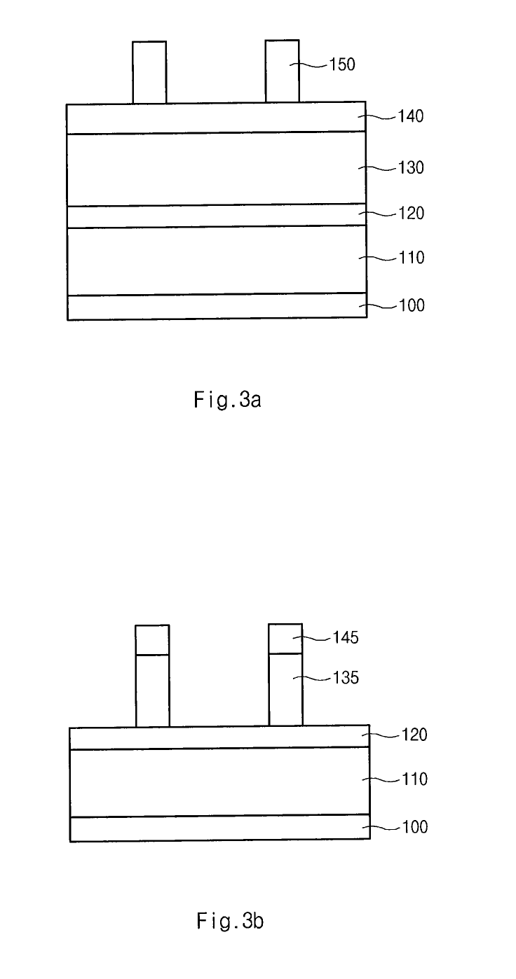

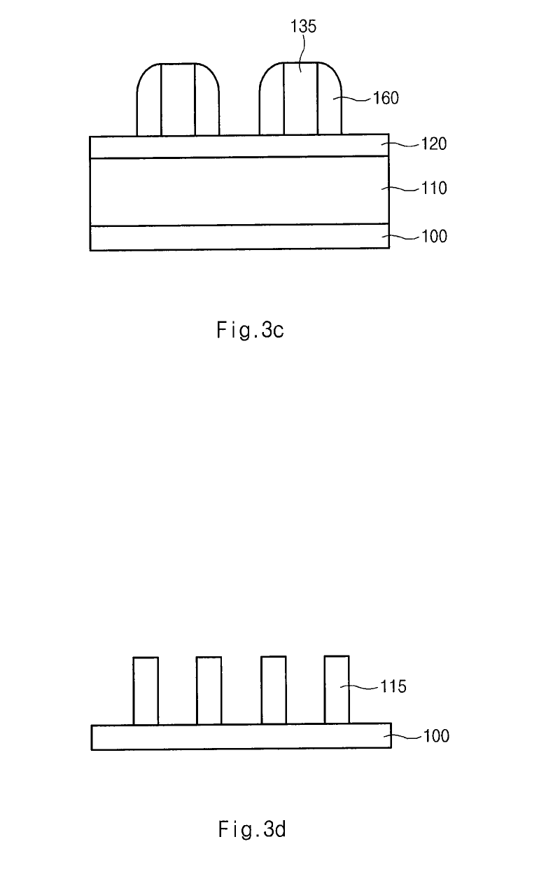

FIGS. 3a to 3d are cross-sectional diagrams illustrating a method for forming a fine pattern of a semiconductor device according to an embodiment of the present invention. In FIG. 3a, a first polysilicon layer 110 is formed over a semiconductor substrate 100. The first polysilicon layer 110 is used as a hard mask. Although not shown an underlying layer such as a gate material layer may be disposed between the first polysilicon layer 110 and the semiconductor substrate 100.

An etch barrier film 120 and a sacrificial oxide film 130 is formed over the first polysilicon layer 110. The etch barrier film 120 includes a nitride film and the sacrificial oxide film 130 includes a PE-TEOS film.

A second polysilicon layer 140 is formed over the sacrificial oxide film 130, and a first photoresist pattern 150 is formed which defines a line pattern. The first photoresist film 150 has a thickness ranging from about 800 Å to about 1200 Å. A critical dimension ratio of line width to the space between line patterns is 1:2˜10.

Referring to FIG. 3b, the second polysilicon layer 140 is etched with the first photoresist pattern 150 as a mask to form a second polysilicon pattern 145 that defines a line pattern. The first photoresist pattern 150 is then removed. The sacrificial oxide film 130 is etched with the first polysilicon pattern 145 to form a sacrificial oxide pattern 135 that defines a line pattern.

Referring to FIG. 3c, a third polysilicon layer (not shown) is formed over the resulting structure including the sacrificial oxide pattern 135. An etch-back process is performed so that the second polysilicon pattern 145 is removed and the third polysilicon layer (not shown) remains on sidewalls of the sacrificial oxide pattern 135 to form a spacer 160. The third polysilicon only remains on the sidewalls of the sacrificial oxide pattern in the present embodiment. A critical dimension (CD) of the spacer 160 corresponds to a line-width of a desired fine pattern.

Referring to FIG. 3d, a wet etching process is performed to remove sacrificial oxide pattern 135. The etch barrier film 120 is etched using the spacer 160 as a mask to form an etch barrier pattern (not shown). The first polysilicon layer 110 is etched using the spacer 160 and the etch barrier pattern (not shown) as a mask to form a first polysilicon pattern 115. The spacer 160 and the etch barrier pattern (not shown) are removed. The semiconductor substrate 100 is etched using the first polysilicon pattern 115 as a mask, or the underlying layer is etched to form a desired fine pattern of the semiconductor device.

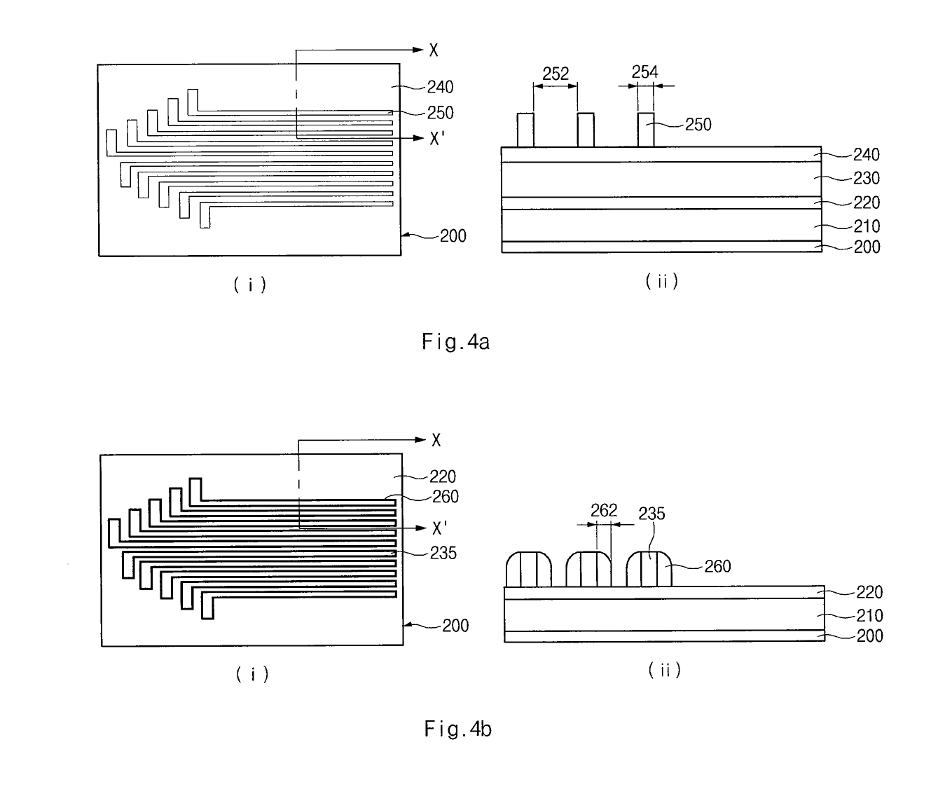

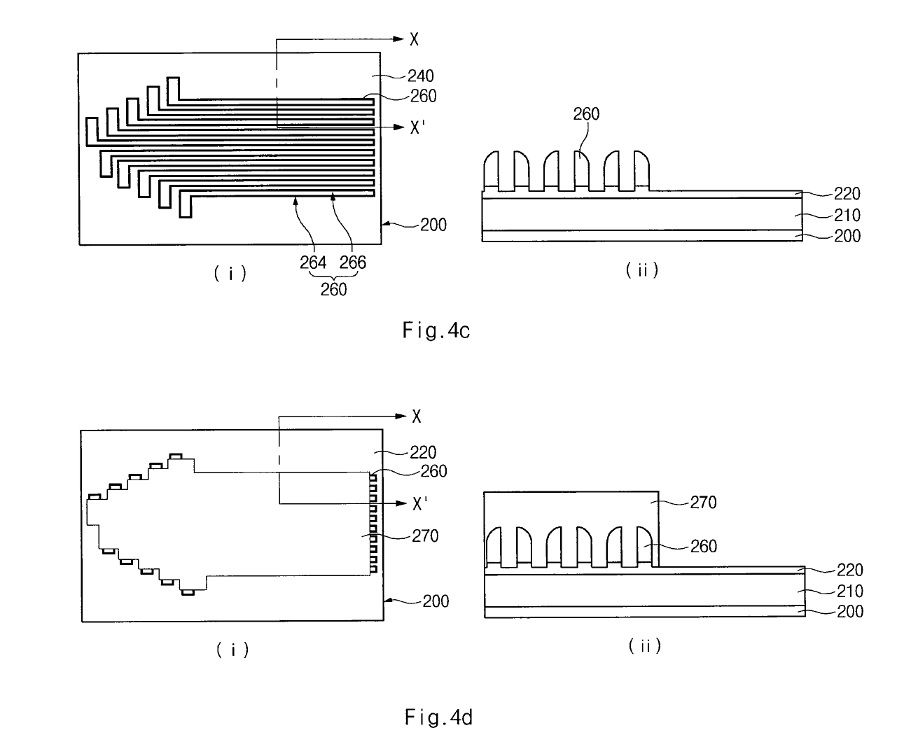

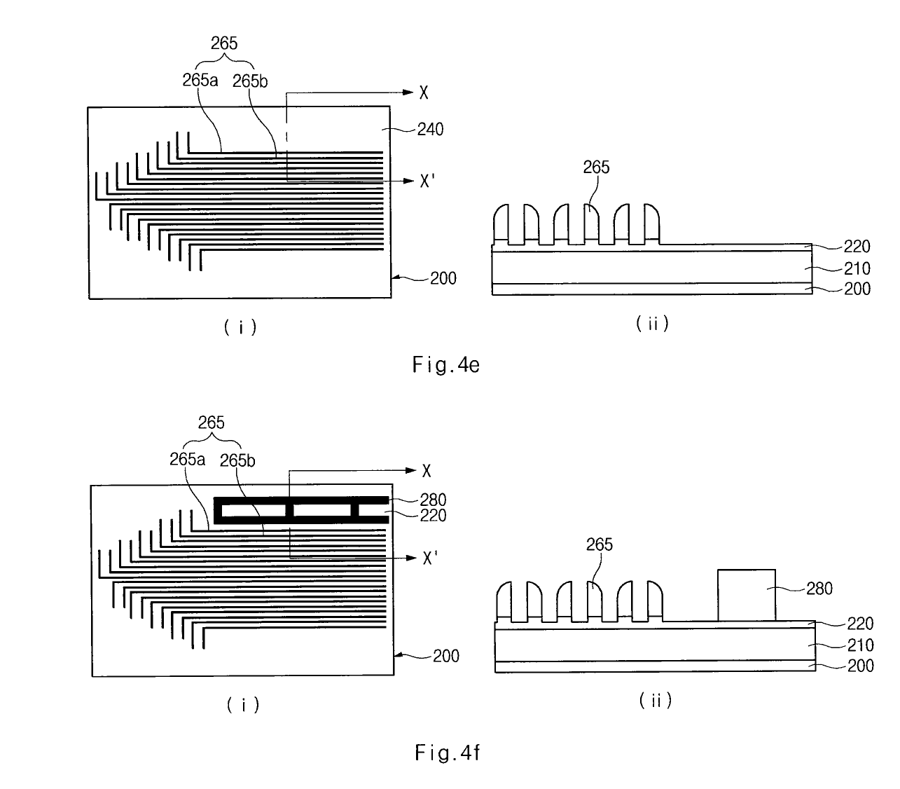

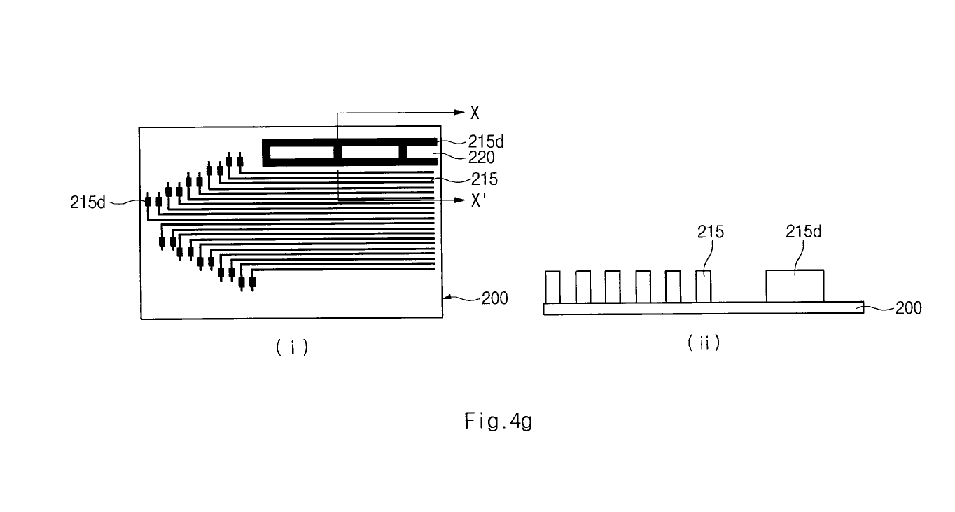

FIGS. 4a to 4g are cross-sectional diagrams illustrating a method for forming a fine pattern of a semiconductor device according to an embodiment of the present invention. FIGS. 4a(i) to 4g(i) are plane diagrams, and FIGS. 4a(ii) to 4g(ii) are cross-sectional diagrams taken along X-X′ of FIGS. 4a(i) to 4g(i).

In FIG. 4a, a first polysilicon layer 210 is formed over a semiconductor substrate 200. The first polysilicon layer 210 is used as a hard mask. Although not shown an underlying layer such as a gate material layer may be disposed between the first polysilicon layer 210 and the semiconductor substrate 200.

An etch barrier film 220 and a sacrificial oxide film 230 is formed over the first polysilicon layer 210. The etch barrier film 220 includes a nitride film, and the sacrificial oxide film 230 includes a PE-TEOS film.

A second polysilicon layer 240 is formed over the sacrificial oxide film 230, and a first photoresist pattern 250 is formed over the second polysilicon layer 240. The first photoresist film 250 has a line pattern. A space 252 between the line patterns is three times larger than a width 254 of the line. The first photoresist pattern 250 has a thickness ranging from about 800 Å to about 1200 Å.

As shown in FIG. 4a(i), the ends of the line patterns are formed to have an L shaped angle. This is done to prevent collapse of the line patterns. The ends are also staggered in the shape of an arrow to avoid interference with each other. The ends are substantially orthogonal to the line patterns in the present embodiment. In other embodiments, the ends may be provided with a slope and may not be orthogonal to the line patterns.

Referring to FIG. 4b, the second polysilicon layer 240 is etched with the first photoresist pattern 250 as a mask to form a second polysilicon pattern (not shown) that defines a line pattern. The first photoresist pattern 250 is then removed. The sacrificial oxide film 230 is etched with the second polysilicon pattern (not shown) to form a sacrificial oxide pattern 235. The sacrificial oxide pattern 235 corresponds to a control gate pattern in the present embodiment. A third polysilicon layer (not shown) is formed over the resulting structure including the sacrificial oxide pattern 235. An etch-back process is performed so that the third polysilicon layer (not shown) remains only on the sidewalls of the sacrificial oxide pattern 235 to form a spacer 260. A line width (or critical dimension) 262 of the spacer 260 corresponds to a line width of a desired pattern to be formed over the substrate 200.

Referring to FIG. 4c, a wet etching process is performed to remove the sacrificial oxide pattern 235. A top portion of the etch barrier nitride film 220 is also etched. The etch barrier nitride film 220 protects the first polysilicon layer 210 during the wet etch process in the present embodiment. The spacer 260 defines an outline of an L-shaped stick since the sacrificial oxide pattern 235 in the middle has been removed. Each L-shaped stick has a first end 264 and a second end 266 that connect two adjacent lines.

Referring to FIG. 4d, a second photoresist pattern 270 is formed over the etch barrier film 220 including the spacer 260. The second photoresist pattern 270 leaves portions of the spacers 260 exposed. The exposed portions include the first ends 264 and the second ends 266.

Referring to FIG. 4d, the exposed portions of the spacers 260 are etched with the second photoresist pattern 270 as a mask. The etch barrier film 220 has a high etching selectivity to polysilicon and protects the first polysilicon layer 210 while the exposed portions of the spacers 260 are etched.

Referring to FIG. 4e, the second photoresist pattern 270 is removed. Since the exposed portions including the first and second ends 264 and 266 are removed, the each spacer 260 is divided to define first and second spacer patterns 265a and 265b. The first and second spacer patterns 265a and 265b are collectively referred to as the spacer patterns 265. The spacer patterns 265 are used to define patterns for the control gates (i.e., control gate patterns).

Referring to FIG. 4f, a third photoresist pattern 280 that is used to define a dummy pattern is formed on one side of a region. In one embodiment, the spacer patterns 265 are formed in a cell region and the third photoresist pattern 280 is formed in a peripheral region adjacent to the outermost spacer pattern 265.

Referring to FIG. 4g, the etch barrier film 220 and the first polysilicon layer 210 are etched using the spacer patterns 265 and the third photoresist pattern 280 as a mask. A dummy pattern 215d is formed along with first polysilicon patterns 215. The dummy pattern 215d is used to prevent collapse of the first polysilicon patterns 215. The semiconductor substrate 200 is etched with the first polysilicon patterns 215 as a mask to form a desired fine pattern. As used herein, the term “pattern” may be used to refer to an individual structure or a plurality of structures based on the context of use.

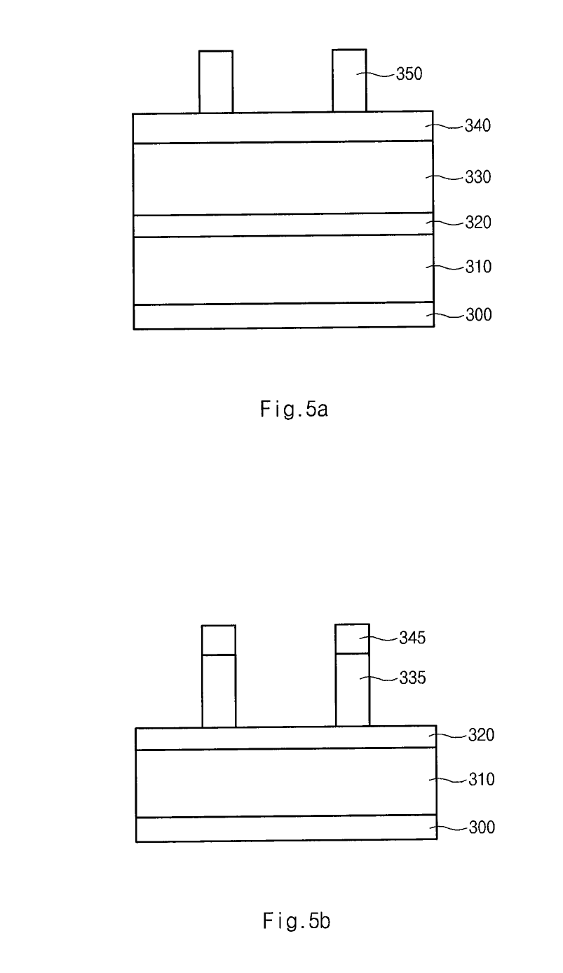

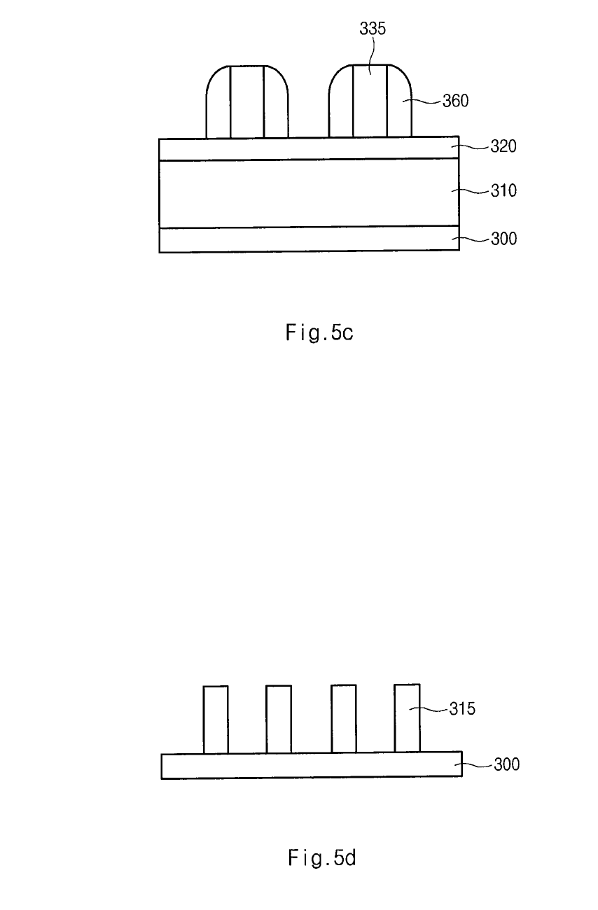

FIGS. 5a to 5d are cross-sectional diagrams illustrating a method for forming a fine pattern of a semiconductor device according to an embodiment of the present invention. In FIG. 5a, a first amorphous carbon (a-C) layer 310 is formed over a semiconductor substrate 300. The first a-C layer 310 is used as a hard mask. Although not shown an underlying layer such as a gate material layer may be disposed between the first a-C layer 310 and the semiconductor substrate 300.

An etch barrier film 320 is formed over the first a-C layer 310. A second a-C layer 330 is formed over the etch barrier film 320. The etch barrier film 320 includes an oxide film.

A first nitride film 340 is formed over the second a-C layer 330, and a first photoresist pattern 350 which defines a line pattern is formed over the first nitride film 340. A critical dimension ratio of line pattern width to a space between line patterns is 1:2˜10. The first photoresist film 350 has a thickness ranging from about 800 Å to 1200 Å.

Referring to FIG. 5b, the first nitride film 340 is etched with the first photoresist pattern 350 as a mask to form a first nitride pattern 345 that defines a line pattern. The first photoresist pattern 350 is then removed. The second a-C layer 330 is etched with the first nitride pattern 345 to form a second a-C pattern 335 that defines a line pattern.

Referring to FIG. 5c, a second nitride film (not shown) is formed over the resulting structure including the second a-C pattern 335. An etch-back process is performed so that the nitride pattern 345 is removed and the second nitride film (not shown) remains only on the sidewalls of the second a-C pattern 335 to form a spacer 360. A critical dimension (CD) of the spacer 360 corresponds to a I line width of a fine pattern to be formed.

Referring to FIG. 5d, an O₂ plasma process is performed to remove the second a-C pattern 335. The etch barrier film 320 is etched with the spacer 360 as a mask to form an etch barrier pattern (not shown). The first a-C layer 310 is etched with the spacer 360 and the etch barrier pattern (not shown) as a mask to form a first a-C pattern 315 that defines a fine pattern. The spacer 360 and the etch barrier pattern (not shown) are removed. The semiconductor substrate 300 is etched with the first a-C pattern 315 as a mask, or an underlying layer is etched to form a fine pattern of a semiconductor device.

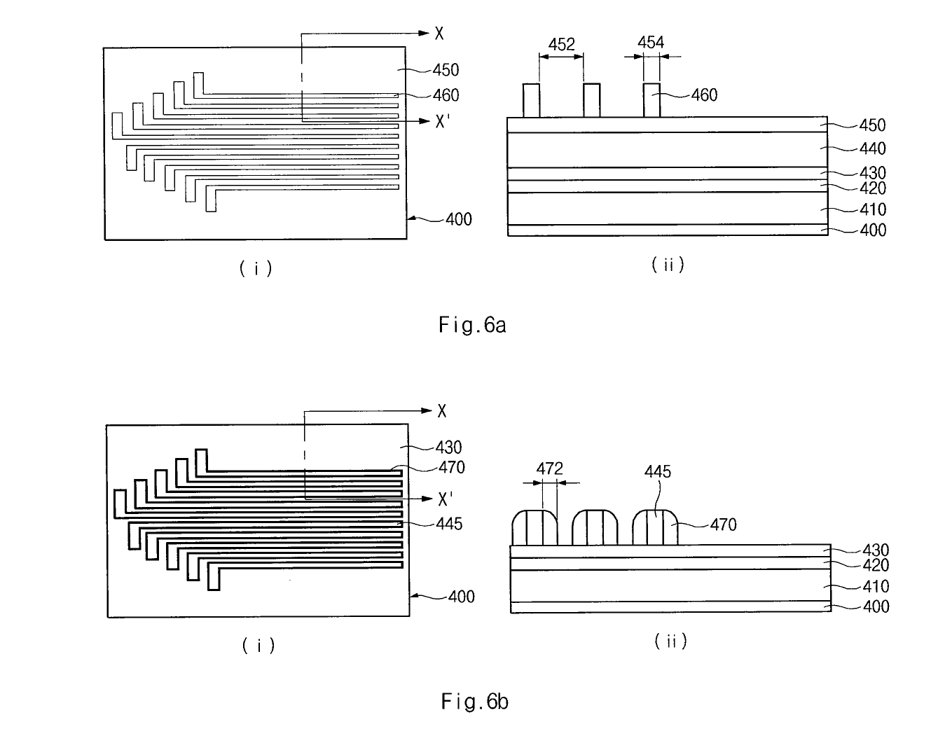

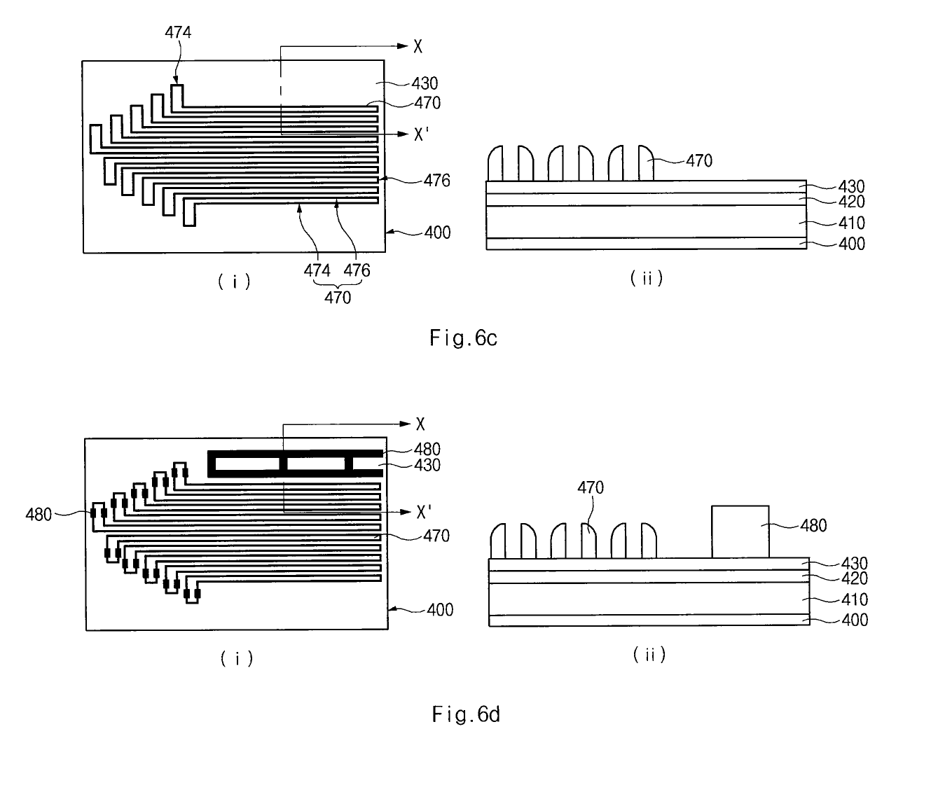

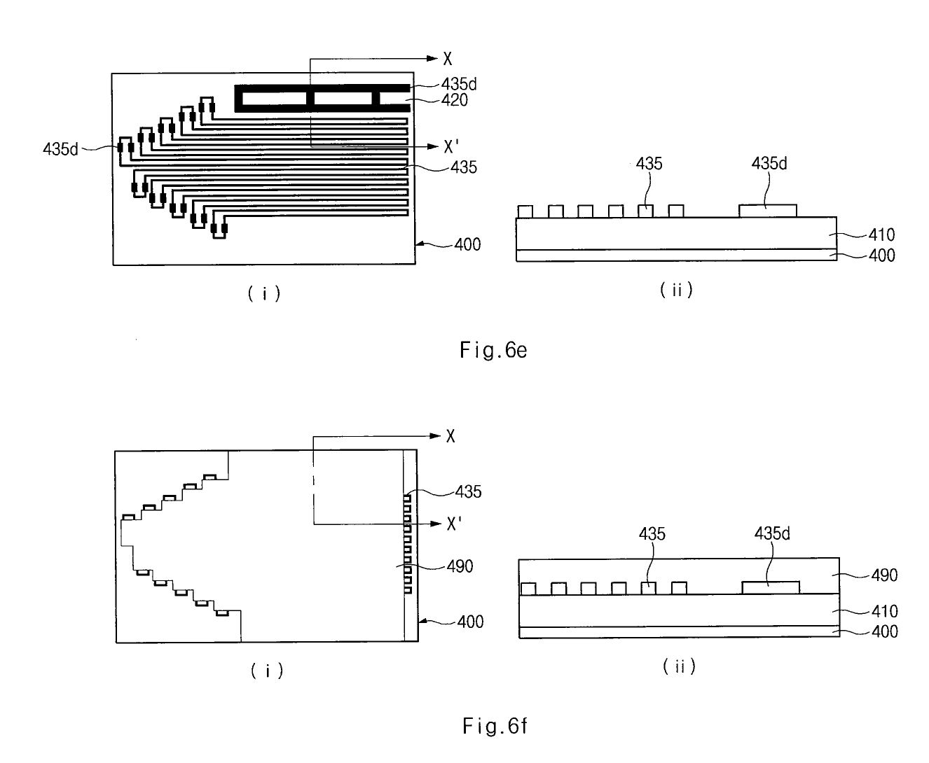

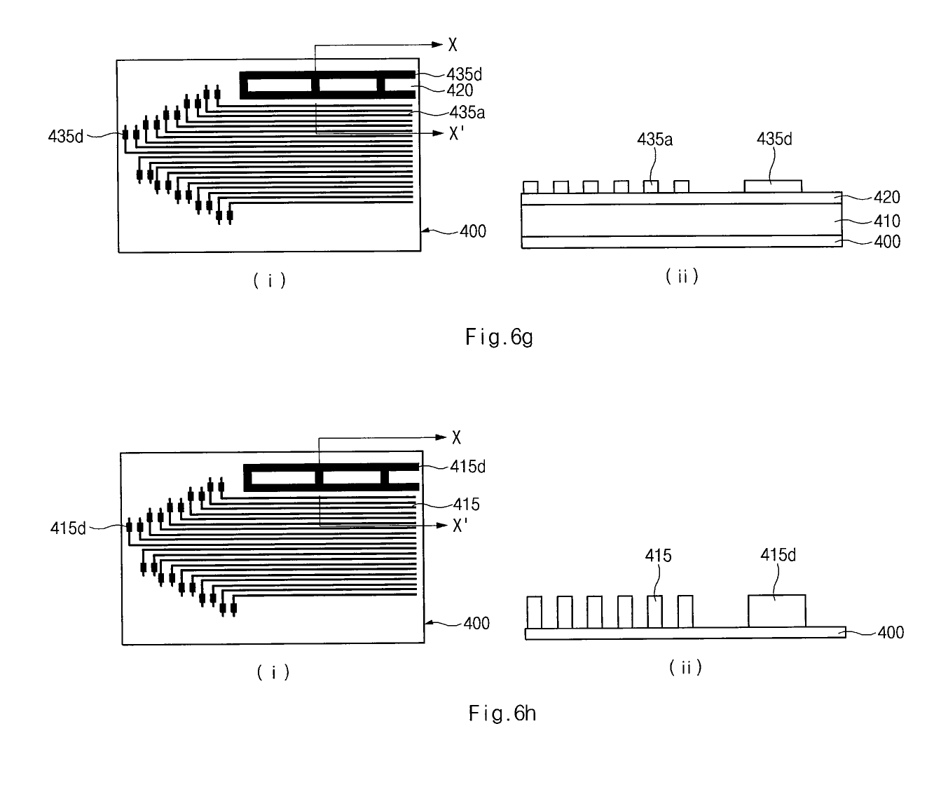

FIGS. 6a to 6h are cross-sectional diagrams illustrating a method for forming a fine pattern of a semiconductor device according to an embodiment of the present invention. FIGS. 6a(i) to 6h(i) are plane diagrams, and FIGS. 6a(ii) to 6h(ii) are cross-sectional diagrams taken along X-X′ of FIGS. 6a(i) to 6h(i).

In FIG. 6a, a first amorphous carbon (a-C) layer 410 is formed over a semiconductor substrate 400. The first a-C layer 410 is used as a hard mask. Although not shown an underlying layer such as a gate material layer may be disposed between the first a-C layer 410 and the semiconductor substrate 400.

An etch barrier film 420 is formed over the first a-C layer 410. A polysilicon layer 430 is formed over the etch barrier film 420. The etch barrier film 420 includes an oxide film.

A second a-C layer 440 is formed over the polysilicon layer 430. A first nitride film 450 is formed over the second a-C layer 440, and a first photoresist pattern 460 is formed over the first nitride film 450. The first photoresist pattern 460 has a line pattern. A space between the line patterns is three times larger than the width of the line pattern. The first photoresist pattern 460 has a thickness ranging from 800 Å to 1200 Å.

As shown in FIG. 6a(i), the ends of the pattern is formed with an L shaped angle to prevent collapse of the line pattern. The L shaped ends are also staggered in the shape of an arrow to avoid interference with each other. The ends may have a slope in other embodiments.

Referring to FIG. 6b, the first nitride film 450 is etched with the first photoresist pattern 460 as a mask to form a nitride pattern (not shown) that defines a line pattern. The first photoresist pattern 460 is then removed. The second a-C layer 440 is etched with the nitride pattern (not shown) as a mask to form a second a-C pattern 445 that defines a control gate pattern.

A second nitride film (not shown) is formed over the resulting structure including the second a-C pattern 445. An etch-back process is performed so that the nitride pattern (not shown) is removed and the nitride film (not shown) remains only on the sidewalls of the second a-C pattern 445 to form a spacer 470. A line width (or CD) 472 of the spacer 470 corresponds to a line width a fine pattern to be formed on the substrate 400.

Referring to FIG. 6c, an O₂ plasma etching process is performed to remove the second a-C pattern 445. The spacer 470 defines an outline of an L-shaped stick since the second a-C pattern 445 in the middle has been removed. Each L-shaped stick has a first end 474 and a second end 476 that connect two adjacent lines. Referring to FIG. 6d, a second photoresist pattern 480 that defines a dummy pattern is formed adjacent to an outermost spacer 470 in order to prevent collapse of that outermost spacer 470.

Referring to FIG. 6e, the polysilicon layer 440 is etched with the spacer 470 and the second photoresist pattern 480 as a mask to form a polysilicon pattern 435 and a dummy polysilicon pattern 435d. The spacer 470 and the second photoresist pattern 480 are removed. The dummy polysilicon pattern 435d is formed before both sides of the polysilicon pattern 435 are etched to divide the pattern 435 into line patterns.

Referring to FIG. 6f, a third photoresist pattern 490 that exposes both sides of the polysilicon pattern 435 is formed over the first a-C layer 410 including the polysilicon pattern 435 and the dummy polysilicon pattern 435d.

Referring to FIG. 6g, the exposed polysilicon pattern 435 is etched with the third photoresist pattern 490 as a mask. Since the etch barrier film 430 has an etching selectivity with polysilicon, the etch barrier film 430 protects the first a-C layer 410, and divides the polysilicon pattern 435 into polysilicon line patterns 435a, where each defines a control gate pattern. The third photoresist pattern 490 is then removed.

Referring to FIG. 6h, the etch barrier film 420 is etched with the polysilicon line pattern 435a and the dummy polysilicon pattern 435d to form an etch barrier pattern (not shown). The first a-C layer 420 is etched with the etch barrier pattern (not shown) as a mask to form a first a-C pattern 415 that defines a flash gate and a dummy a-C pattern 415d. The polysilicon pattern 435a and the dummy polysilicon pattern 435d are removed. The etch barrier pattern (not shown) is removed. The semiconductor substrate 400 is then etched with the first a-C pattern 415 and the dummy a-C pattern 415d as a mask to form a fine pattern.

As described above, according to an embodiment of the present invention, a method for forming a fine pattern of a semiconductor device comprises forming a line/space pattern over a semiconductor substrate and forming a spacer including a polysilicon layer or an a-C layer on sidewalls of the line pattern. The spacer is used as a hard mask pattern that defines a fine pattern to improve yield and reliability of the device.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for forming a semiconductor device, the method comprising:
forming a hard mask film and an etch barrier film over a substrate;
forming a sacrificial pattern over the etch barrier film;
forming a spacer on sidewalls of the sacrificial pattern;
removing the sacrificial pattern; and
etching the etch barrier film and the hard mask film using the spacer as an etch mask to form a hard mask pattern,
wherein the substrate is etched using the hard mask pattern.

2. The method according to claim 1, wherein the hard mask film includes a polysilicon film or an amorphous carbon.

3. The method according to claim 1, wherein the etch barrier film includes a nitride film or an oxide film.

4. The method according to claim 1, wherein the sacrificial pattern includes an oxide film or an amorphous carbon.

5. The method according to claim 1, wherein the sacrificial pattern including at least first and second lines, wherein a space defined by the first and second lines is 2 to 10 times that of a width of the first line.

6. The method according to claim 1, wherein the spacer includes a polysilicon film or nitride film.

7. The method according to claim 1, wherein the sacrificial pattern includes an oxide film and the oxide film is removed by a wet etch process.

8. The method according to claim 1, wherein the sacrificial pattern includes an amorphous film and the amorphous carbon film is removed in an environment including O₂ plasma.

9. A method for forming a semiconductor device, the method comprising:
forming a hard mask film and an etch barrier film over a substrate;
forming a sacrificial oxide pattern over the etch barrier film, the sacrificial oxide pattern being formed in a cell region;
forming a spacer on sidewalls of the sacrificial oxide pattern;
removing the sacrificial oxide pattern, so that the spacer defines a solid portion and a hollow portion provided within the solid portion;
forming a first photoresist pattern over the spacer, the first photoresist pattern exposing at least one end portion of the spacer;
etching an exposed end portion of the spacer using the first photoresist pattern as an etch mask, so that the spacer is divided into a first pattern and a second pattern;
forming a second photoresist pattern in a peripheral region adjacent to the cell region;
etching the etch barrier film and the hard mask film using the second photoresist pattern and the first and second patterns of the spacer as an etch mask to form a hard mask pattern,
wherein the hard mask pattern is used to etch the substrate.

10. The method according to claim 9, wherein the hard mask film includes a polysilicon film.

11. The method according to claim 9, wherein the etch barrier film includes a nitride film.

12. The method according to claim 9, wherein the sacrificial oxide pattern is a line shaped that corresponds to a pattern for a control gate of the semiconductor device.

13. The method according to claim 9, wherein the-forming-a-spacer includes:
forming a polysilicon film on the etch barrier film including the sacrificial oxide pattern; and
performing an etch-back process on the polysilicon film.

14. The method according to claim 9, wherein the sacrificial oxide pattern is removed by a wet etch process.

15. A method for forming a semiconductor device, the method comprising:
forming a first hard mask film over a semiconductor substrate;
forming a etch barrier film and a polysilicon film over the first hard mask film;
forming a second hard mask pattern over the polysilicon film;
forming a spacer on sidewalls of the second hard mask pattern, the spacer and the second hard mask pattern being formed in a cell region;
removing the second hard mask pattern;
forming a first photoresist pattern that is used to form a dummy pattern on the polysilicon film in a peripheral region adjacent to the cell region;
etching the polysilicon film using the first photoresist pattern and the spacer as an etch mask to form a polysilicon pattern and a dummy polysilicon pattern;
removing the first photoresist pattern and the spacer;
forming a second photoresist pattern exposing an end portion of the polysilicon pattern over the polysilicon film;
etching an exposed end portion of the polysilicon pattern suing the second photoresist pattern as an etch mask to divide the polysilicon pattern into first and second line patterns;
removing the second photoresist pattern;
etching the etch barrier film and the first hard mask film using the first and second line patterns and the dummy polysilicon pattern as an etch mask; and
removing the polysilicon line patterns, the dummy polysilicon pattern and the etch barrier film.

16. The method according to claim 15, wherein the first hard mask film and the second hard mask pattern include an amorphous carbon.

17. The method according to claim 15, wherein the etch barrier film includes an oxide film.

18. The method according to claim 15, wherein the second hard mask pattern has a line shape corresponding to a pattern of a control gate of the semiconductor device.

19. The method according to claim 15, wherein the-forming-a-spacer-on-sidewalls-of-the-second-hard-mask-pattern step includes:
forming a nitride film over the polysilicon film including the second hard mask pattern; and
performing an etch-back process on the polysilicon film.

20. The method according to claim 15, wherein the second hard mask pattern is etched using O₂ plasma.
